(19) United States
(12) Patent Application Publication
(10) Pub. No.: US 2011/0278706 A1
(43) Pub. Date: Nov. 17, 2011

(54) Power Electronic Device Package

(75) Inventor: Emmanuel Orpia Herras, Carmona (PH)

(73) Assignee: iQXPRZ Power Inc.

(21) Appl. No.: 13/104,319

(22) Filed: May 10, 2011

Related U.S. Application Data
(60) Provisional application No. 61/333,277, filed on May 11, 2010.

(51) Int. Cl. H01L 23/495; H01L 21/98; H01L 23/52

(52) U.S. Cl. 257/675; 257/691; 438/122; 257/E23.051; 257/E23.141; 257/E21.705

(57) ABSTRACT

A power electronic device package comprising a base member, a device layer, multiple leads, and an encapsulant is provided. The base member is thermally conductive for heat dissipation. The device layer comprises one or more power electronic devices mounted on the base member. The power electronic devices are selectively electrically connected to each other and to the base member to form an internal electronic circuit. The leads extend outwardly from the base member and are electrically connected to the internal electronic circuit. The encapsulant encases the internal electronic circuit, a portion of the base member, and a portion of the leads. The power electronic device package is configured as a transfer molded power module with multiple leads and increased power handling capability. In an embodiment, the base member is electrically conductive to operate as an electrical terminal. The base member may also be isolatably connected to the internal electronic circuit.

### CROSS REFERENCE TO RELATED APPLICATIONS

This application claims the benefit of provisional patent application No. 61/333,277 titled “Power Electronic Device Package”, filed on May 11, 2010 in the United States Patent and Trademark Office.

The specification of the above referenced patent application is incorporated herein by reference in its entirety.

### BACKGROUND

Semiconductor technology continues to advance rapidly, producing smaller and more efficient devices that challenge the packaging and assembly technology for accommodating complex configurations in a single package with improved layouts and designs, without compromising quality and efficiency.

The use of inverters in various applications is now common due to significant energy savings over non-inverter based designs. There is a need for inverter based systems that are more compact, reliable, and that have lower overall costs.

There are several methods of designing a power circuit for different applications. The conventional approach is to combine several packaged discrete components to form a whole circuit. This requires a large number of components, which produces a bigger board footprint and requires a larger heat sink. Moreover, the components are required to be connected externally. The integrity of external connection of the components has a significant impact on the overall efficiency of the system. Thus, most of the applications that require a larger number of components resort to power modules since several power semiconductor devices need to be combined to form a desired power circuit. Advanced packaging technology involving packaging of a power device gate drive, a control circuit, and a protection circuit in some cases, requires more complex integration. Plastic housing and potting methods are widely used. There is a need for a transfer molding technique for packaging power electronic devices that is cost-efficient and reliable.

The existing power semiconductor packages, for example, existing transistor outline (TO) packages such as the TO247 packages, offer limited current handling capability to cater to medium to high power application requirements. Conventionally, a number of devices packaged in separate TO247 packages are mounted in an array form to enable paralleling of their external leads, which is disadvantageous.

Hence, there is a need for a power electronic device package that is configured as a transfer molded power module with multiple leads and increased power handling capability, and that provides an improved internal chip mounting area, a small footprint, a compact package design, and flexibility in design, where internal chip mounting patterns can be easily changed to suit application needs.

### SUMMARY OF THE INVENTION

This summary is provided to introduce a selection of concepts in a simplified form that are further described in the detailed description of the invention. This summary is not intended to identify key or essential inventive concepts of the claimed subject matter, nor is it intended for determining the scope of the claimed subject matter.

The power electronic device package and method for creating the power electronic device package disclosed herein addresses the above stated need for a power electronic device package that is configured as a transfer molded power module with multiple leads and increased power handling capability, and that provides an improved internal chip mounting area, a small footprint, a compact package design, and flexibility in design, where internal chip mounting patterns can be easily changed to suit application needs. The power electronic device package disclosed herein is an alternative to discrete power devices in inverter-based systems and other applications that require a combination of several discrete components in their power circuit sections. Furthermore, the power electronic device package disclosed herein has an increased power handling capability, thereby allowing the use of large electronic chips in a single transistor outline (TO) package. In addition to integration to form a desired specific application power circuit, the power electronic device package disclosed herein also allows paralleling of power electronic devices to achieve, for example, high current rating power switches. The power electronic device package disclosed herein allows a large chip with a high current rating to be mounted in a single package, or a number of chips to be mounted and connected in parallel in a single package.

The power electronic device package disclosed herein comprises a base member, a device layer, multiple leads, and an encapsulant. The power electronic device package disclosed herein is configured, for example, as a multiple leads expanded TO247 package. The base member is thermally conductive for heat dissipation. As used herein, the term “base member” refers to, for example, a copper base member, a direct copper bonded substrate, a combination of the copper base member and the direct copper bonded substrate, an intermetallic substrate (IMS), a plastic molded copper base member, etc.

The device layer comprises one or more power electronic devices, for example, semiconductor devices and their components, mounted on the base member. One or more power electronic devices are selectively electrically connected to each other and to the base member to form an internal electronic circuit. The base member of the power electronic device package disclosed herein comprises a mounting area that enables the mounting of the power electronic devices in multiple configurations. The mounted power electronic devices are selectively connected to each other and to the base member, for example, by wire bonds, soldered interconnects, or a combination thereof, to form the internal electronic circuit.

The leads extend outwardly from the base member. The leads are electrically connected to the internal electronic circuit formed by the power electronic devices on the base member. The leads are, for example, power leads, signal leads, or a combination thereof. The multiple leads can be combined to increase current handling capability of the leads and the power electronic device package. The encapsulant encases the internal electronic circuit formed by the power electronic devices on the base member, a portion of the base member, and a portion of the leads. The encased internal electronic circuit formed by the power electronic devices on the base member, the portion of the base member, and the portion of the leads in strip form are singulated to create the power electronic device package. An opposing surface of the base member is rearwardly exposed in the power electronic device package.

In an embodiment, the base member of the power electronic device package disclosed herein is isolatably connected to the internal electronic circuit formed by the selective electrical connection of one or more of the power electronic devices to each other and to the leads. In this embodiment, the power electronic device package disclosed herein further comprises a substrate mounted on the base member for selectively isolating the power electronic devices on the device layer from each other and from the base member. In an embodiment, a direct copper bonded substrate itself serves as the base member. The substrate is, for example, a metallized substrate, a direct copper bonded substrate, etc. The material of the substrate is made of, for example, aluminum nitride, aluminum oxide, etc., or another functionally equivalent material. In an example, when the base member in the power electronic device package disclosed herein is a copper base member, a metallized substrate or a direct copper bonded substrate is mounted on the copper base member for selectively isolating the power electronic devices on the device layer from each other and from the copper base member.

The power electronic devices can be mounted directly on the base member, or on the substrate mounted on the base member, or on a combination thereof, for example, via mounting pads, a supplementary substrate, or a combination thereof. In an embodiment, the power electronic device package disclosed herein further comprises a printed circuit board (PCB) layer comprising one or more of complementary electronic devices and auxiliary electronic devices disposed in conjunction with the device layer mounted on the base member or the substrate mounted on the base member. The printed circuit board layer is directly mounted on top of the device layer or mounted adjacent to the device layer. The printed circuit board layer is connected to the device layer, for example, by jumper wires, soldered connecting terminal pins, wire bonded aluminum wires, wire bonded gold wires, or any combination thereof.

In an embodiment, the power electronic device package disclosed herein further comprises one or more mounting holes for enabling direct installation to an external heat sink, for example, using mounting screws.

In an embodiment, the base member is electrically conductive to operate as an electrical terminal. In this embodiment, the base member, for example, the copper base member is configured as an active terminal for connection to the internal electronic circuit formed by the power electronic devices mounted on the base member. The base member serves as a common active terminal for paralleling a combination of power electronic devices on the base member to achieve high current ratings. The power electronic device package disclosed herein controls and converts electrical power.

### BRIEF DESCRIPTION OF THE DRAWINGS

The foregoing summary, as well as the following detailed description of the invention, is better understood when read in conjunction with the appended drawings. For the purpose of illustrating the invention, exemplary constructions of the invention are shown in the drawings. However, the invention is not limited to the specific methods and components disclosed herein.

FIG. 1 exemplarily illustrates an orthogonal view of a power electronic device package with mounting holes, showing power electronic devices directly mounted on a base member.

FIG. 2 exemplarily illustrates an orthogonal view of the power electronic device package without mounting holes, showing power electronic devices directly mounted on the base member.

FIGS. 3A-3B exemplarily illustrate an embodiment of the power electronic device package, showing a substrate mounted between a base member and a device layer of the power electronic device package.

FIG. 4A exemplarily illustrates a side exploded view of the power electronic device package.

FIG. 4B exemplarily illustrates a side assembled view of the power electronic device package.

FIG. 5A exemplarily illustrates a side exploded view of an embodiment of the power electronic device package comprising a substrate mounted between the base member and the device layer of the power electronic device package.

FIG. 5B exemplarily illustrates a side assembled view of the embodiment of the power electronic device package comprising the substrate mounted between the base member and the device layer of the power electronic device package.

FIG. 6 exemplarily illustrates a side assembled view of an embodiment of the power electronic device package comprising a printed circuit board layer mounted on the device layer.

FIG. 7 exemplarily illustrates an embodiment of the power electronic device package, showing a combination of electrically connected power electronic devices forming an internal electronic circuit.

FIG. 8 exemplarily illustrates an embodiment of the power electronic device package, showing a single power electronic device mounted on the base member.

FIG. 9 exemplarily illustrates an embodiment of the power electronic device package, showing power electronic devices connected in parallel to achieve a high current rating of the power electronic device package.

FIG. 10 exemplarily illustrates a dual heat sink lead frame for an embodiment of the power electronic device package without the substrate.

FIG. 11 exemplarily illustrates a single heat sink lead frame for an embodiment of the power electronic device package without the substrate.

FIG. 12 exemplarily illustrates an embodiment of a disassembled power electronic device package with a substrate, showing a copper base member, the substrate, and a lead frame without a heat sink.

FIG. 13 exemplarily illustrates the embodiment of an assembled power electronic device package with a substrate, showing a copper base member, the substrate, and a lead frame without a heat sink.

FIG. 14A exemplarily illustrates a top perspective view of the power electronic device package.

FIG. 14B exemplarily illustrates a bottom perspective view of the power electronic device package, showing opposing surfaces of two base members.

FIG. 15 illustrates a method for creating a power electronic device package configured as a power module with multiple leads and increased power handling capability.

### DETAILED DESCRIPTION OF THE INVENTION

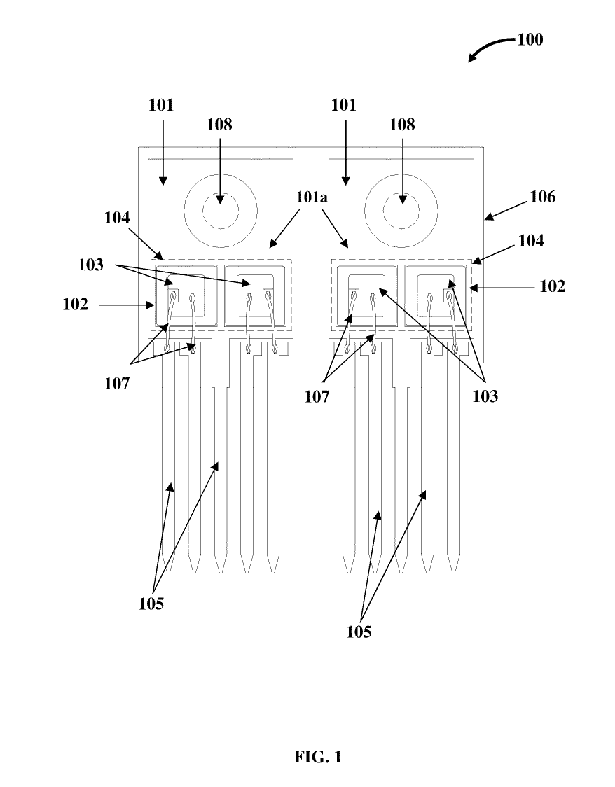

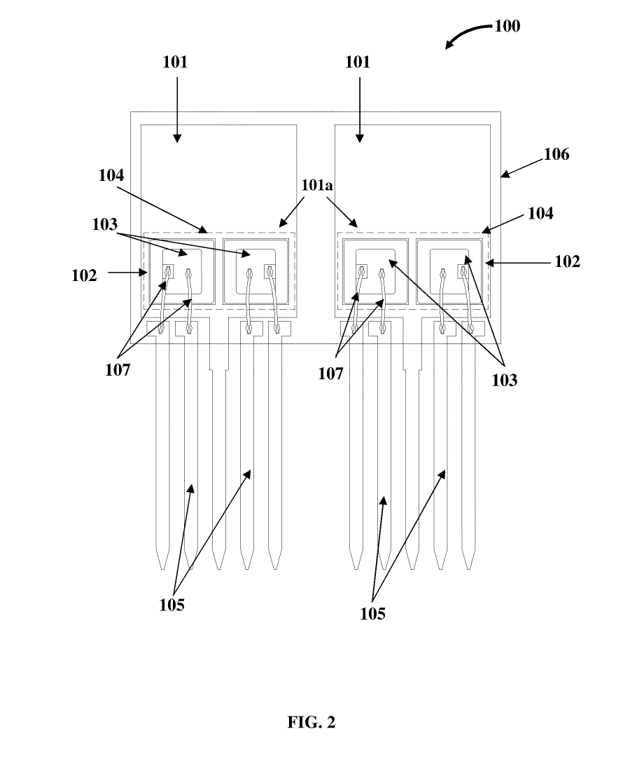

FIG. 1 and FIG. 2 exemplarily illustrate orthogonal views of a power electronic device package 100 with and without mounting holes 108 respectively, showing power electronic devices 103 directly mounted on the base member 101. The power electronic device package 100 disclosed herein is configured, for example, as a multiple leads expanded transistor outline (TO) package, that is, a multiple leads expanded TO247 package. The power electronic device package 100 disclosed herein comprises a base member 101, a device layer 102, multiple leads 105, and an encapsulant 106.

The base member 101 is thermally conductive for heat dissipation. As used herein, the term “base member” refers to, for example, a copper base member, a direct copper bonded (DCB) substrate, a combination of the copper base member and the direct copper bonded substrate, an intermetallic substrate (IMS), a plastic molded copper base member, etc. The base member 101 disclosed in the detailed description of FIGS. 1-2 is, for example, a copper base member. In an embodiment, two or more base members 101 of multiple designs that are not internally connected can be provided in the power electronic device package 100 based on the circuit design as exemplarily illustrated in FIGS. 1-2.

The device layer 102 of the power electronic device package 100 disclosed herein comprises one or more power electronic devices 103 mounted on the base member 101. As used herein, the term “power electronic devices” refers to, for example, power semiconductors, semiconductor components, and other electronic components that are required to be mounted on the base member 101 for electronic applications. A single power electronic device 103 or a combination of power electronic devices 103 of different configurations or interconnections can be mounted on the base member 101. The base member 101 of the power electronic device package 100 disclosed herein comprises a mounting area 101a that enables mounting of one or more power electronic devices 103 in multiple configurations.

The power electronic devices 103 are rigidly mounted on the base member 101 using a solder preform 110, for example, alloys of lead, tin and silver, alloys of tin, silver and copper, alloys of tin and silver, other solder materials, etc. The rigidly mounted power electronic devices 103 produce heat during operation. The base member 101 is the thermally conductive part of the power electronic device package 100. The base member 101 therefore serves as a thermal path for the heat produced by the power electronic devices 103 during operation.

One or more of the power electronic devices 103 are selectively electrically connected to each other and to the base member 101 to form an internal electronic circuit 104. As used herein, the term “electronic circuit” refers to a circuit composed of individual electronic components, power electronic devices 103 such as resistors, transistors, capacitors, inductors, diodes, etc., connected, for example, by conductive wires or copper traces through which electric current can flow. The combination of components and wires in the internal electronic circuit 104 allows various simple and complex operations to be performed, for example, power switching, amplification of signals, power conditioning, power conversion, motion control, etc. The power electronic devices 103 are selectively connected to each other and to the base member 101, for example, by wire bonds 107, soldered interconnects, or a combination thereof, to form the internal electronic circuit 104. In an embodiment, the internal electronic circuit 104 is connected using terminals or clips. The free ends of the terminals or clips are mounted on the base member 101 using a solder preform 110, for example, alloys of lead, tin and silver, alloys of tin, silver and copper, alloys of tin and silver, etc. In another embodiment, the internal electronic circuit 104 is formed by connecting the power electronic devices 103 and the leads 105 using wire bonds 107 as exemplarily illustrated in FIGS. 1-2, FIG. 4B, FIG. 5B, and FIGS. 6-9. The wire bonds 107 are, for example, made of aluminum, gold, or copper material, in a wire form or a ribbon form.

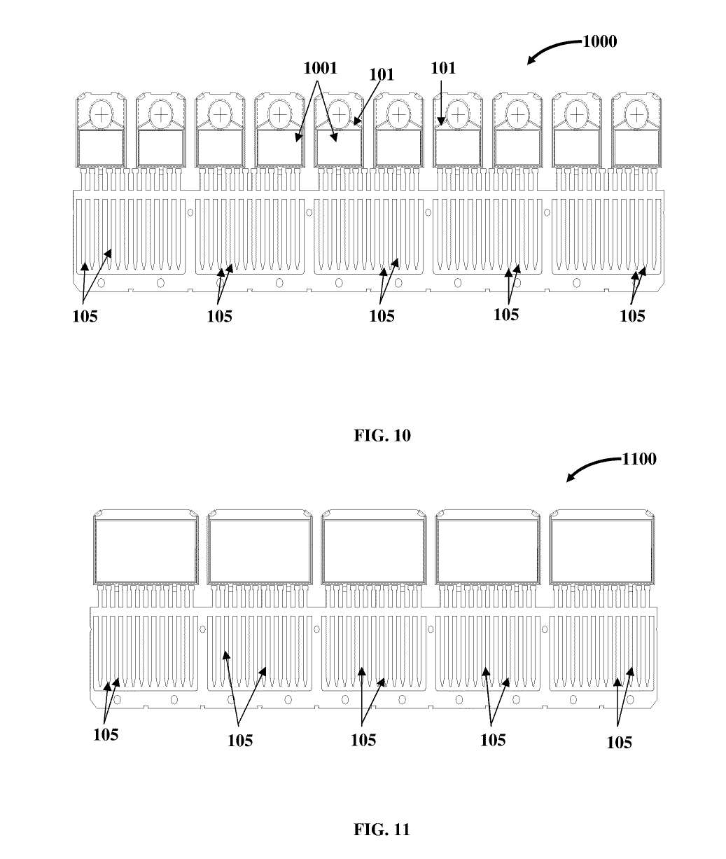

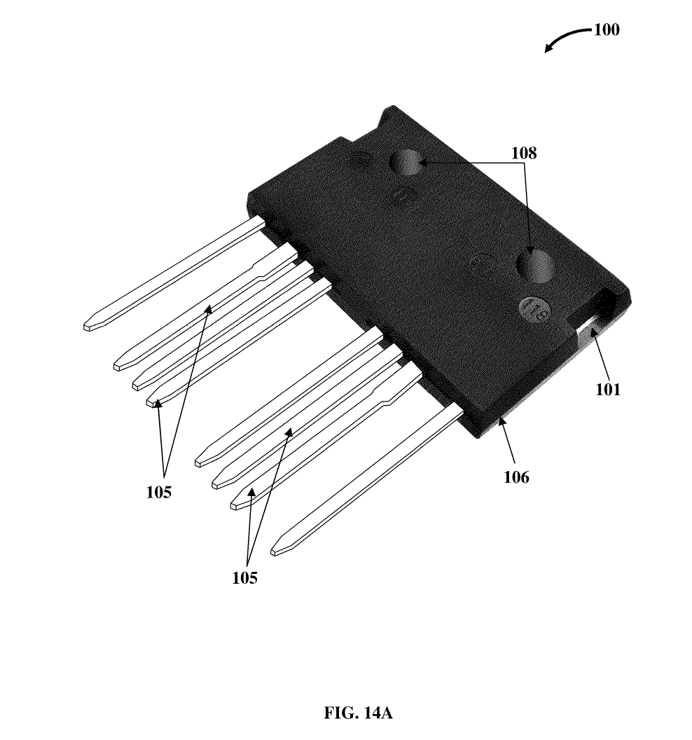

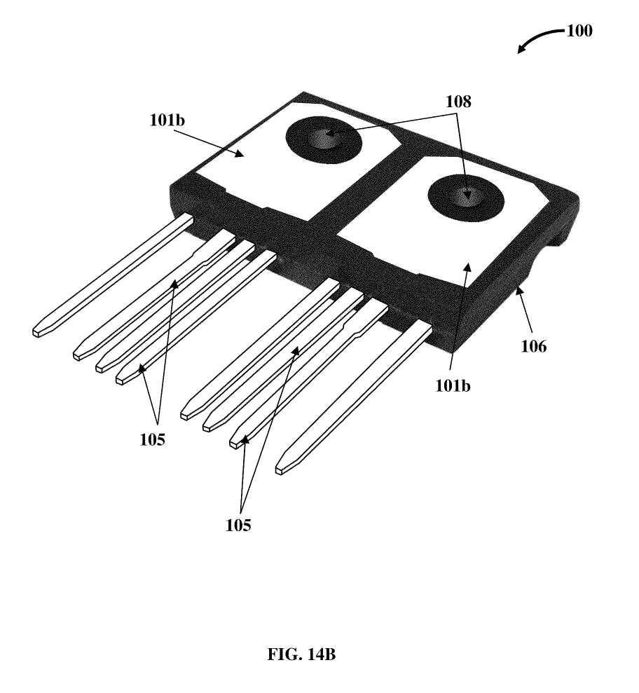

The base member 101 is of different patterns depending on the design needs. In an embodiment, the base member 101 is designed with two or more mounting pads 1001 that are not connected to each other as exemplarily illustrated in FIG. 10. In an embodiment, the base member 101 is a direct copper bonded substrate on which metallization patterns 1201 serve as the mounting pads for one or more power electronic devices 103 as exemplarily illustrated in FIGS. 12-13. The power electronic devices 103 are mounted on the base member 101, for example, via one or more copper base mounting pads 1001, a supplementary substrate such as a direct copper bonded substrate or a metallized substrate, or a combination thereof. In an embodiment, the power electronic devices 103 are mounted directly on a direct copper bonded substrate without a copper base member. An opposing surface 101b of the base member 101 is rearwardly exposed in the power electronic device package 100 as exemplarily illustrated in FIG. 14B.

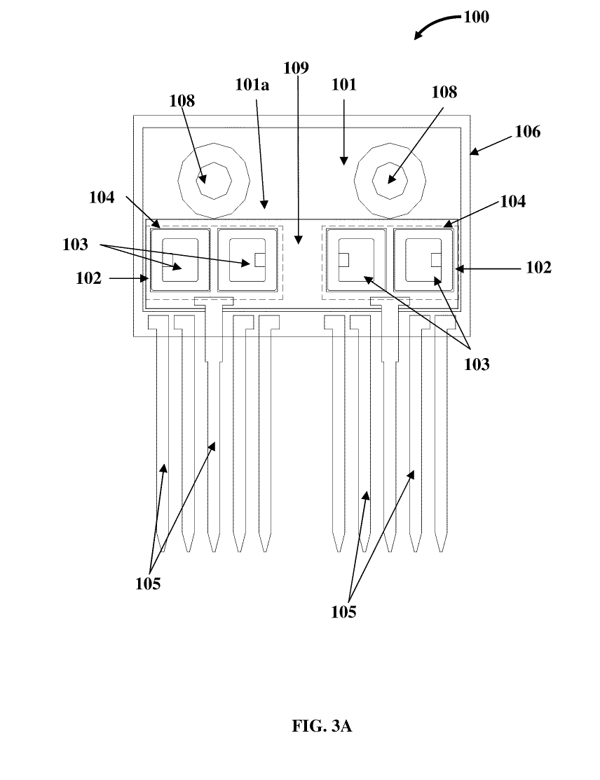

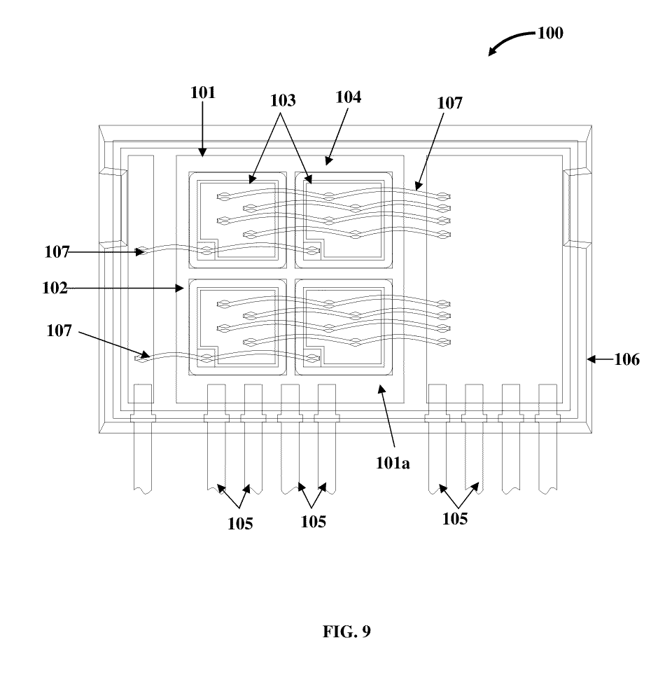

In an embodiment, the base member 101 is electrically conductive to operate as an electrical terminal. For example, the base member 101 is configured as an active terminal for connection to the internal electronic circuit 104 formed by the power electronic devices 103 mounted on the base member 101. In an example, a copper base member serves as a common active terminal for the power electronic devices 103 connected in parallel, as exemplarily illustrated in FIG. 9, to achieve high current ratings. Therefore, the base member 101 serves as both a conductive path to dissipate heat produced by the power electronic devices 103 and simultaneously acts as an active electrical terminal during operation of the power electronic device package 100, when the base member 101 is not isolated from the power electronic devices 103 by a substrate 109 exemplarily illustrated in FIGS. 3A-3B.

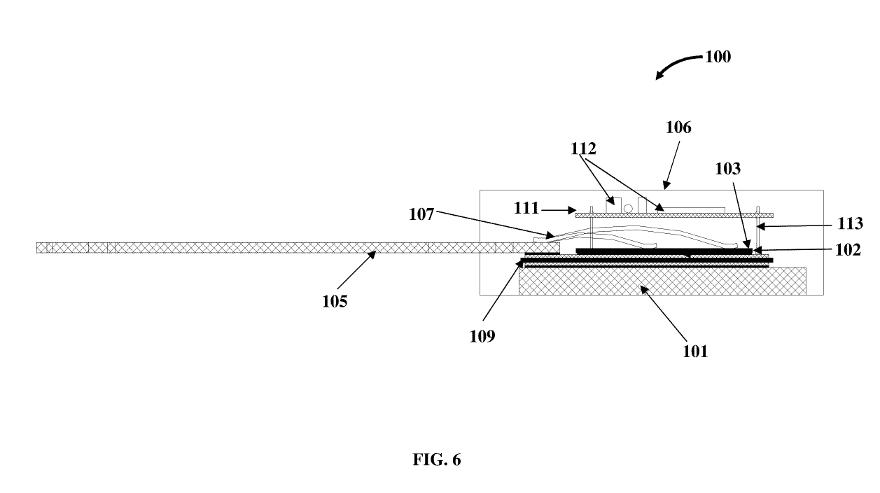

In an embodiment, the power electronic device package 100 further comprises a printed circuit board (PCB) layer 111, as exemplarily illustrated in FIG. 6, comprising one or more of complementary electronic devices and auxiliary electronic devices 112 disposed in conjunction with the device layer 102 mounted on the base member 101.

Multiple leads 105 of the power electronic device package 100 disclosed herein extend outwardly from the base member 101. The leads 105 are electrically connected to the internal electronic circuit 104 formed by the power electronic devices 103 on the base member 101. The leads 105 are external conductive terminals that connect to the internal electronic circuit 104. A portion of the leads 105 protrudes out of an encapsulant 106 used to encase the power electronic device package 100. The leads 105 are, for example, made of copper, alloys of copper, alloys of aluminum, tin, alloys of tin, other conductive metals, etc. The leads 105 are, for example, power leads and/or signal leads of different sizes, or a combination thereof. Power leads refer to leads designed for carrying high input current and high output current. Signal leads refer to leads designed for carrying low signal current for gate driving and sensing. The number of leads 105 to be mounted in the power electronic device package 100 depends on the internal electronic circuit 104 to be formed. The number of leads 105 can be increased or decreased depending on the requirements of the circuit design.

In an embodiment, the leads 105 are connected directly to the base member 101 in the form of lead frames, for example, 1000, 1100, and 1202 as exemplarily illustrated in FIGS. 10-13. In another embodiment, the base member 101 and the leads 105 are singulated parts which are connected to each other during assembly of the power electronic device package 100. The leads 105 can be designated according to the circuit design and internally connected in the power electronic device package 100 as defined. The multiple leads 105 are selectively combinable to increase current handling capacity of the leads 105 and the power electronic device package 100.

The encapsulant 106 of the power electronic device package 100 disclosed herein encases the internal electronic circuit 104 formed by the power electronic devices 103 on the base member 101, a portion of the base member 101, and a portion of the leads 105. The encapsulant 106 is designed, for example, as a rectangular plastic body with or without mounting holes 108. The encapsulant 106 protects the internal components, for example, 101, 103, 107, etc., of the power electronic device package 100 from external environmental effects, for example, dust, moisture, etc. The encapsulant 106 is made, for example, of an epoxy molding compound that protects the internal electronic circuit 104 from environmental effects. Moreover, the encapsulant 106 is made of a non-conductive material that serves as insulation for the base member 101 and for each conductive part within the power electronic device package 100 and the power electronic devices 103 in the power electronic device package 100, and is thermally conductive for dissipating heat from the power electronic device package 100 during operation.

Encapsulation is performed using a transfer molding technique. The transfer molding technique refers to a pressure molding method where heated and pressurized resin is poured into a metal mold and enclosed, enabling a manufacturer to make multiple molds simultaneously. The transfer molding technique provides high accuracy of transfer molding tooling and low cycle time of the process. In an embodiment, encapsulation is performed using a potting technique. The potting technique requires a plastic casing or housing that serves as plastic walls before applying a liquid potting material. The liquid potting material is, for example, a liquid resin.

In an embodiment, the power electronic device package 100 comprises one or more mounting holes 108, as exemplarily illustrated in FIG. 1, for enabling direct installation to an external heat sink (not shown). The mounting holes 108 are through holes that extend from the encapsulant 106 down to the base member 101. The mounting holes 108 allow easy and direct installation of the power electronic device package 100 to an external auxiliary cooling heat sink, for example, using mounting screws instead of clips that are used in conventional device packages. The external heat sink is made of, for example, aluminum, aluminum alloys, etc., of multiple different designs. In another embodiment, the power electronic device package 100 is designed without mounting holes 108 as exemplarily illustrated in FIG. 2.

The power electronic device package 100 disclosed herein controls and converts electrical power. The power electronic device package 100 is configured as a transfer molded power module with multiple leads 105 and increased power handling capability. The power electronic device package 100 is used for high current and high voltage applications. Moreover, the power electronic device package 100 has an increased electrical power handling capability and therefore allows the use of larger power electronic devices 103 in a transistor outline package. In addition to integration to form a desired specific application power circuit, the power electronic device package 100 offers an alternative approach in paralleling power electronic devices 103 to achieve, for example, high current rating power switches. Paralleling of multiple power electronic devices 103 is achieved by mounting the power electronic devices 103 in parallel to a common base member 101. The common base member 101 serves as the active terminal for the combined power electronic devices 103 connected in parallel to achieve high current ratings.

The power electronic device package 100 allows mounting and parallel connection of one or more large power electronic devices 103 and other components with high current rating in a single package 100. The leads 105 can be combined to increase current handling capability of the power electronic device package 100. Thus, the mounting area 101a is smaller and the package cost is lower. Internal chip or device mounting patterns can be easily changed based on application requirements. The configuration of the leads 105 can be defined according to the requirements of the circuit design. The efficiency is also improved with the power electronic devices 103 being internally connected to form the internal electronic circuit 104.

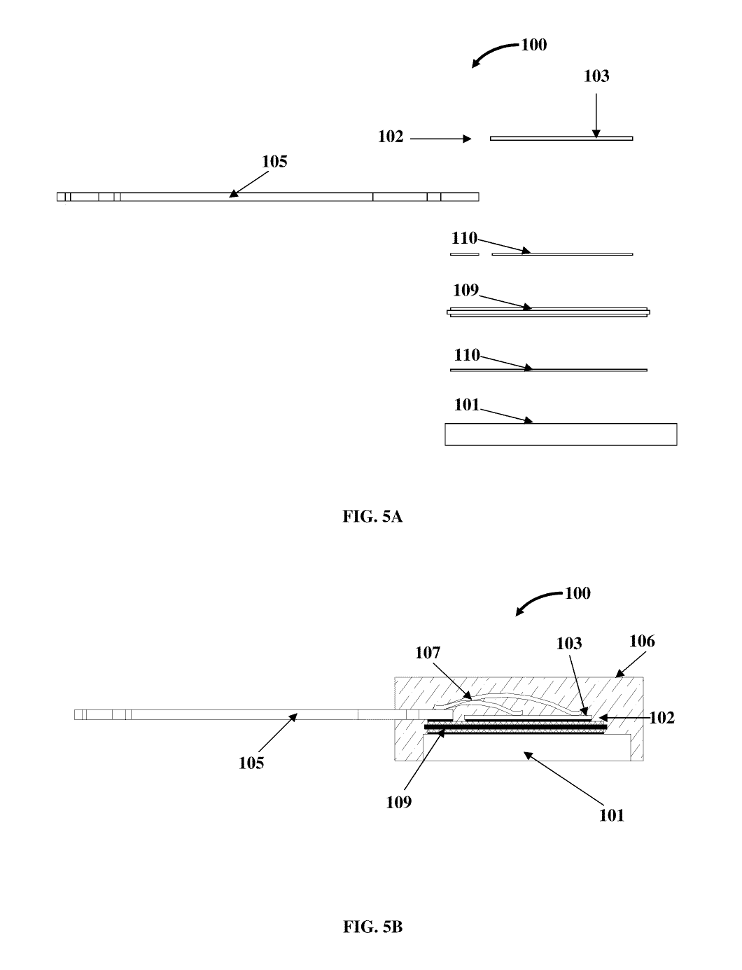

FIGS. 3A-3B exemplarily illustrate an embodiment of the power electronic device package 100, showing a substrate 109 mounted between the base member 101 and the device layer 102 of the power electronic device package 100. FIG. 3A exemplarily illustrates a power electronic device package 100 with mounting holes 108 and with a substrate 109 disposed between the base member 101 and the power electronic devices 103. FIG. 3B exemplarily illustrates a power electronic device package 100 without mounting holes 108 but with a substrate 109 disposed between the base member 101 and the power electronic devices 103. In an embodiment, the base member 101 is isolatably connected to the internal electronic circuit 104 formed by the selective electrical connection of one or more of the power electronic devices 103 to each other and to the leads 105. The base member 101 is isolated from the internal electronic circuit 104 as exemplarily illustrated in FIGS. 3A-3B. In this embodiment, the power electronic device package 100 disclosed herein further comprises the substrate 109 mounted on the base member 101 for selectively isolating one or more of the power electronic devices 103 on the device layer 102 from each other and from the base member 101 as exemplarily illustrated in FIGS. 3A-3B and FIGS. 5A-5B, forming a thermally conductive path between the substrate 109 and the base member 101. The substrate 109 is made of a material comprising, for example, aluminum nitride, aluminum oxide, etc., or another functionally equivalent material. In an embodiment, the substrate 109 is metallized, for example, with nickel, silver, etc., or is direct copper bonded. In an example, when the base member 101 in the power electronic device package 100 disclosed herein is a copper base member, a substrate 109 such as a metallized substrate or a direct copper bonded substrate is mounted on the copper base member for selectively isolating the power electronic devices 103 on the device layer 102 from each other and from the copper base member.

One or more power electronic devices 103 are directly mounted on the base member 101, or on the substrate 109 mounted on the base member 101, or on a combination thereof, and connected, for example, by wire bonds 107, soldered interconnects, or a combination thereof to form the internal electronic circuit 104. In an embodiment, the printed circuit board layer 111 comprising one or more of complementary electronic devices and auxiliary electronic devices 112 is disposed in conjunction with the device layer 102 mounted on the base member 101, or on the substrate 109 mounted on the base member 101 as disclosed in the detailed description of FIG. 6. In an embodiment, the leads 105 are mounted on the substrate 109, for example, using solder materials.

The substrate 109 is used when the power electronic devices 103 are mounted on the same plane but need to be isolated from each other. In an embodiment, the substrate 109 is used when the power electronic devices 103 need to be isolated from the base member 101. The substrate 109 is, for example, a metallized substrate, a direct copper bonded (DCB) substrate, etc.

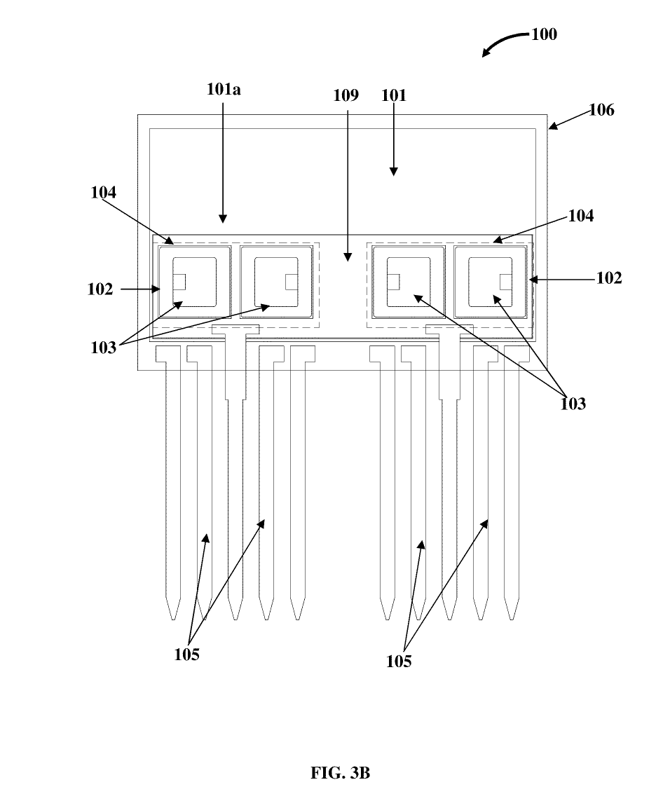

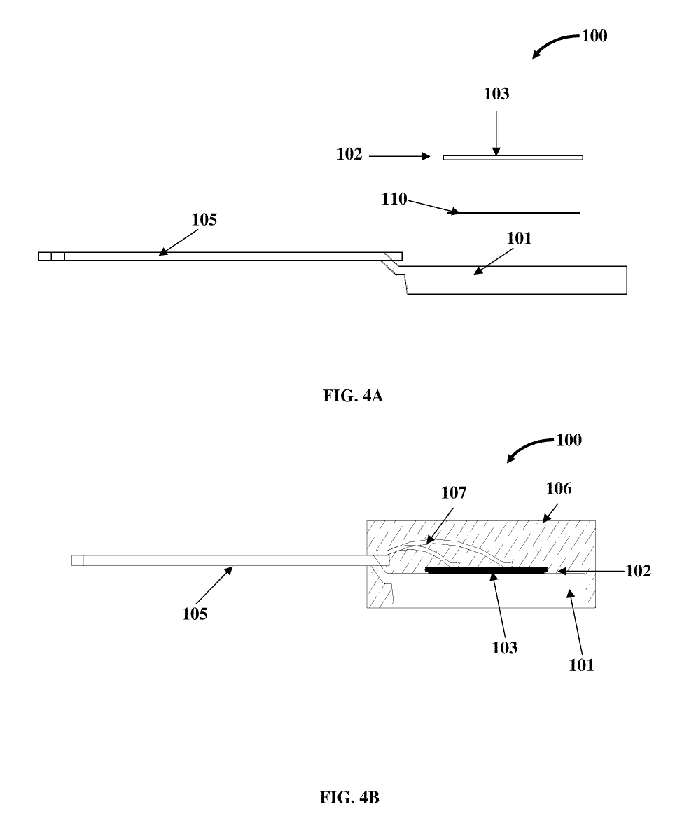

FIG. 4A exemplarily illustrates a side exploded view of the power electronic device package 100. As exemplarily illustrated in FIG. 4A, the power electronic device package 100 comprises the base member 101, the leads 105 extending outwardly from the base member 101, and the device layer 102 containing the power electronic devices 103 as disclosed in the detailed description of FIGS. 1-2.

FIG. 4B exemplarily illustrates a side assembled view of the power electronic device package 100. The device layer 102 comprising the power electronic devices 103 is rigidly attached to the base member 101 using a solder preform 110 exemplarily illustrated in FIG. 4A. The power electronic devices 103 are also electrically connected to the base member 101 using solder preforms 110, for example, alloys of lead, tin and silver, alloys of tin, silver and copper, alloys of tin and silver, etc. The power electronic devices 103 are directly connected to the leads 105, for example, using wire bonds 107. The encapsulant 106 encases the base member 101, the power electronic devices 103 mounted on the base member 101, a portion of the leads 105, and the wire bonds 107. The opposing surface 101b of the base member 101 is rearwardly exposed in the power electronic device package 100, as exemplarily illustrated in FIG. 14B, for effective dissipation of heat produced by the mounted power electronic devices 103.

FIG. 5A exemplarily illustrates a side exploded view of an embodiment of the power electronic device package 100 comprising a substrate 109 mounted between the base member 101 and the device layer 102 of the power electronic device package 100. As exemplarily illustrated in FIG. 5A, the power electronic device package 100 disclosed herein comprises the base member 101, the leads 105, the substrate 109, and the device layer 102 containing the power electronic devices 103 as disclosed in the detailed description of FIGS. 1-2.

FIG. 5B exemplarily illustrates a side assembled view of the embodiment of the power electronic device package 100 comprising the substrate 109 mounted between the base member 101 and the device layer 102 of the power electronic device package 100. The substrate 109 is rigidly mounted onto the base member 101 using a layer of a solder preform 110 exemplarily illustrated in FIG. 5A, thus forming a thermally conductive path between the substrate 109 and the base member 101. The solder perform is made of, for example, alloys of lead, tin and silver, alloys of tin, silver and copper, alloys of tin and silver, etc. The power electronic devices 103 of the device layer 102 are isolated from the base member 101 using the substrate 109. The device layer 102 comprising the power electronic devices 103 is rigidly connected to the substrate 109 using another layer of the solder preform 110 exemplarily illustrated in FIG. 5A. The substrate 109 is used to isolate the internal electronic circuit 104 formed by the electrically connected power electronic devices 103 mounted on the substrate 109 from the base member 101 as exemplarily illustrated in FIGS. 3A-3B. The power electronic devices 103 are directly connected to the leads 105, for example, using wire bonds 107. The encapsulant 106 encases the base member 101, the substrate 109, the power electronic devices 103 mounted on the substrate 109, a portion of the leads 105, and the wire bonds 107.

FIG. 6 exemplarily illustrates a side assembled view of an embodiment of the power electronic device package 100 comprising a printed circuit board (PCB) layer 111 mounted on the device layer 102. The PCB layer 111 comprises one or more of complementary electronic devices and auxiliary electronic devices 112 disposed in conjunction with the device layer 102 mounted directly on the base member 101, or on the substrate 109 mounted on the base member 101 as exemplarily illustrated in FIG. 6. A control circuit can be integrated to the power electronic device package 100 using the additional PCB layer 111. In this embodiment, the power electronic device package 100 is configured as an intelligent power module. An intelligent power module refers to a power module in which a gate control and protection circuit is included within the power electronic device package 100.

The PCB layer 111 comprises, for example, a printed circuit board, gate drivers, and passive components electrically connected to each other. The PCB layer 111 is connected to the device layer 102 that contains the power electronic devices 103, for example, by soldered connecting terminal pins 113, soldered jumper wires, wire bonded aluminum wires, wire bonded gold wires, etc., or any combination thereof. As exemplarily illustrated in FIG. 6, the PCB layer 111 is connected to the device layer 102, for example, by soldered connecting terminal pins 113. In an embodiment, the PCB layer 111 further comprises soldering pads on which additional leads 105 are soldered using a solder preform 110, for example, alloys of lead, tin and sliver, alloys of tin, silver and copper, alloys of tin and silver, etc. The PCB layer 111 is connected to the device layer 102 depending on the layout requirements. In an embodiment, the PCB layer 111 is directly mounted on top of the device layer 102. In another embodiment, the PCB layer 111 is mounted adjacent to the device layer 102.

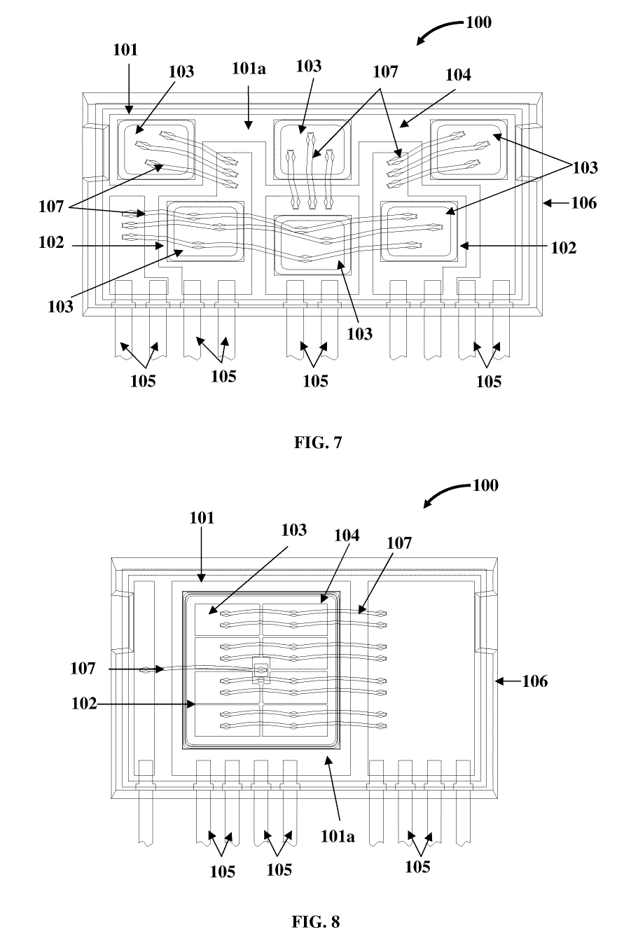

FIG. 7 exemplarily illustrates an embodiment of the power electronic device package 100, showing a combination of electrically connected power electronic devices 103 forming an internal electronic circuit 104. Multiple power electronic devices 103 are electrically connected, for example, using the wire bonds 107 to form the internal electronic circuit 104 on the base member 101. In this embodiment, the base member 101 is, for example, a direct copper bonded substrate only or a direct copper bonded substrate mounted on a copper base member. In an embodiment, the power electronic devices 103 are electrically connected, for example, by terminals and clips soldered using a solder preform 110, a combination of terminals and clips soldered using a solder preform 110, etc.

FIG. 8 exemplarily illustrates an embodiment of the power electronic device package 100 with a single power electronic device 103 mounted on the base member 101. A large power electronic device 103 with a high current rating is mounted and attached to the base member 101 using a layer of the solder preform 110, for example, alloys of lead, tin and silver, alloys of tin, silver and copper, alloys of tin and silver, etc. In this embodiment, the base member 101 is, for example, a direct copper bonded substrate only or a direct copper bonded substrate mounted on a copper base member. Connections are then provided, for example, through wire bonds 107 in the internal electronic circuit 104 of the power electronic device package 100. A number of leads 105 are combined to create high current terminals for the power electronic device 103.

FIG. 9 exemplarily illustrates an embodiment of the power electronic device package 100, showing the power electronic devices 103 connected in parallel to achieve a high current rating of the power electronic device package 100. The leads 105 are combined to increase the current handling capability of the leads 105. Conventional device packages, for example, a typical three leads TO247 package can only handle a certain amount of current per lead. The three leads in the TO247 package are assigned to three terminals of a transistor. Of the three terminals of the transistor, two terminals have a high current rating and the third terminal is provided for low gate current. The power electronic device package 100 disclosed herein comprising multiple leads 105 allows combining two or more leads 105 for each of the two terminals of the transistor to increase the capacity to handle current as needed by the design, due to the available number of leads 105. Each of the leads 105 are of the same size as that of the leads in the TO247 package.

FIG. 10 exemplarily illustrates a dual heat sink lead frame 1000 for an embodiment of the power electronic device package 100 exemplarily illustrated in FIGS. 1-2, without the substrate 109. The dual heat sink lead frame 1000 comprises a number of power electronic devices 103 attached, wirebonded, and transfer molded with epoxy. The leads 105 in the dual heat sink lead frame 1000 can be directly connected to the base member 101 during assembly. The dual heat sink lead frame 1000 is then singulated after the transfer molding process to form the finished power electronic device package 100. The power electronic device package 100 is incorporated in a strip form or in a lead frame form during assembly of the power electronic device package 100. In an example, the dual heat sink lead frame 1000 is composed of five power electronic device packages 100. In an embodiment, the dual heat sink lead frame 1000 can be used for creating a power electronic device package 100, where a substrate 109 mounted between the base member 101 and the device layer 102 isolates the device layer 102 from the base member 101.

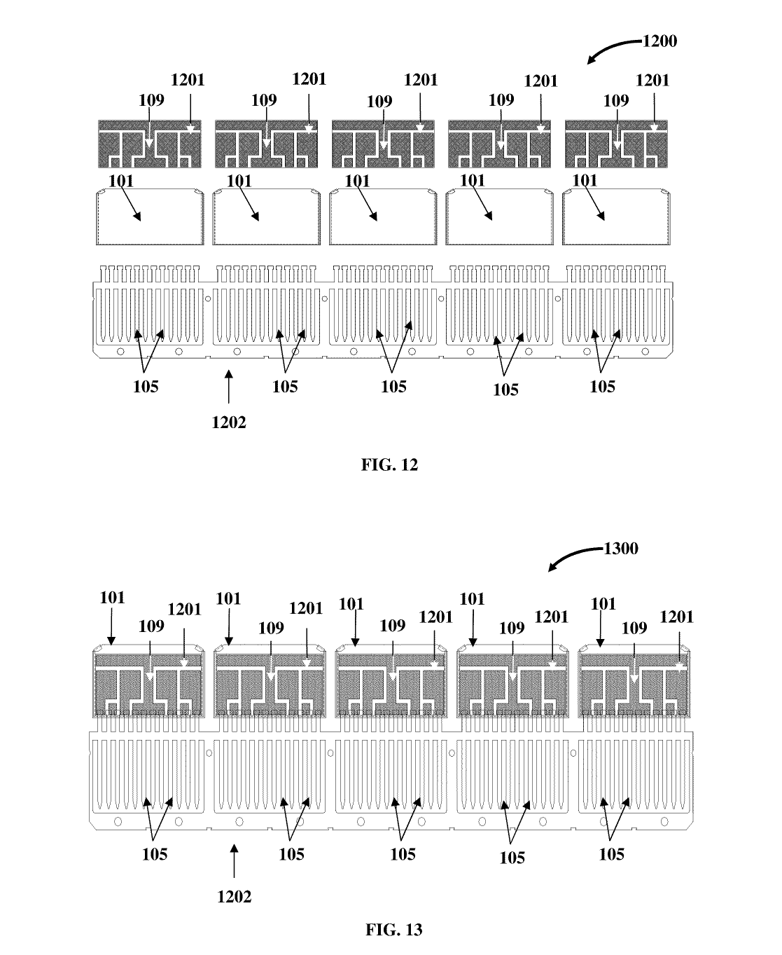

FIG. 11 exemplarily illustrates a single heat sink lead frame 1100 for an embodiment of the power electronic device package 100 exemplarily illustrated in FIGS. 1-2, without the substrate 109. In an embodiment, the single heat sink lead frame 1100 is used for creating a power electronic device package 100, where the substrate 109 mounted between the base member 101 and the device layer 102 isolates the device layer 102 from the base member 101. This is a variation of the lead frame design exemplarily illustrated in FIG. 10. The leads 105 of the single heat sink lead frame 1100 are connected directly to the base member 101.

FIG. 12 exemplarily illustrates an embodiment of a disassembled power electronic device package 1200 with a substrate 109, showing a copper base member 101, the substrate 109, and a lead frame 1202 without a heat sink. In an embodiment, the substrate 109 is a direct copper bonded substrate on which metallization patterns 1201 serve as the mounting pads for one or more power electronic devices 103 as exemplarily illustrated in FIGS. 12-13.

FIG. 13 exemplarily illustrates an embodiment of an assembled power electronic device package 1300 with a substrate 109, showing a copper base member 101, the substrate 109, and a lead frame 1202 without a heat sink. The power electronic device package 1300 comprises the leads 105, the base member 101, and the substrate 109. The substrate 109 is used when the power electronic devices 103 are mounted on the same plane but need to be isolated from each other. In an embodiment, the substrate 109 is used when the power electronic devices 103 need to be isolated from the base member 101.

FIG. 14A exemplarily illustrates a top perspective view of the power electronic device package 100. The power electronic device package 100 is transfer molded as an integrated and miniaturized power module in a single and compact encapsulant 106. The power electronic device package 100 exemplarily illustrated in FIG. 14A comprises two mounting holes 108 that extend from the encapsulant 106 down to the base member 101 for enabling direct installation to an external heat sink (not shown), for example, using mounting screws (not shown). The number of leads 105 that extend outwardly from the base member 101 can be varied depending on the requirement of the internal electronic circuit 104 exemplarily illustrated in FIGS. 1-2.

FIG. 14B exemplarily illustrates a bottom perspective view of the power electronic device package 100, showing opposing surfaces 101b of two base members 101. The opposing surfaces 101b of the base members 101 are rearwardly exposed in the power electronic device package 100 for effective dissipation of heat produced by the power electronic devices 103 mounted on the base members 101. For example, the flat sides or opposing surfaces 101b of the base members 101 are exposed at the backside of the power electronic device package 100, serving as a conductive path for heat dissipation during actual use of the power electronic device package 100. FIG. 14B exemplarily illustrates two mounting holes 108 on the rearwardly exposed opposing surfaces 101b of the base members 101.

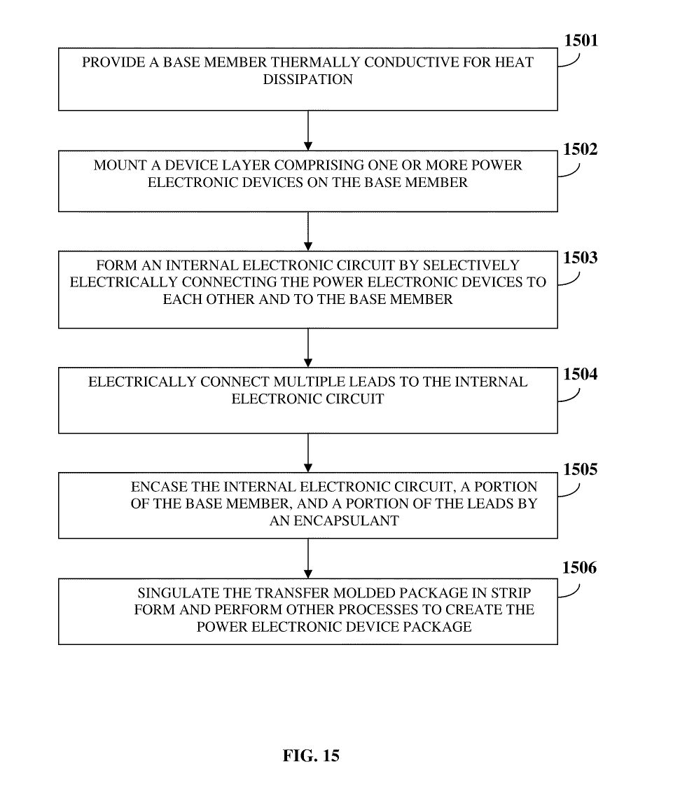

FIG. 15 illustrates a method for creating a power electronic device package 100 configured as a power module with multiple leads 105 and increased power handling capability. A base member 101 thermally conductive for heat dissipation as disclosed in the detailed description of FIGS. 1-2 is provided 1501. A device layer 102 comprising one or more power electronic devices 103 is mounted 1502 on the base member 101 via a mounting die attach pad 1001, as exemplarily illustrated in FIG. 10, based on a desired layout. A soft solder material or solder preform 110 is used as a medium for attaching the device layer 102 to the base member 101 in a soft solder attachment process. A conductive or non-conductive epoxy can also be used as a medium to mount the power electronic devices 103 on the base member 101. The power electronic devices 103 are selectively electrically connected to each other and to the base member 101 to form 1503 an internal electronic circuit 104 as exemplarily illustrated in FIGS. 1-2.

Multiple leads 105 are electrically connected 1504 to the internal electronic circuit 104 formed by the power electronic devices 103 on the base member 101. The leads 105 extend outwardly from the base member 101. The leads 105 are selectively combinable to increase current handling capacity of the leads 105 and the power electronic device package 100. The base member 101 serves as a common active terminal for paralleling a combination of power electronic devices 103 on the base member 101 to achieve high current ratings. The base member 101 is electrically conductive and configured to operate as an active electrical terminal for connection to the internal electronic circuit 104 formed by the power electronic devices 103 mounted on the base member 101.

In an embodiment, a substrate 109 is mounted on the base member 101 for selectively isolating the power electronic devices 103 from each other and from the base member 101. The leads 105, in a singular form or in the form of a lead frame, are then mounted on the substrate 109 using the solder preform 110 as the medium. The leads 105 in the singular form can be joined together with other materials during assembly. In an embodiment, a direct copper bonded (DCB) substrate is used to replace the base member 101. The terminal pins (not shown) of the power electronic devices 103 are connected to the designated leads 105, for example, using wire bonds 107. In an embodiment, if solderable power electronic devices 103 are required to be connected in the power electronic device package 100, solderable copper terminals (not shown) can be used instead of wire bonds 107.

When a PCB layer 111, as exemplarily illustrated in FIG. 6, is required as part of the power electronic device package 100, terminal pins of the power electronic devices 103 are first mounted on a predetermined location on either the base member 101 or the substrate 109. The other free ends of the terminal pins of the power electronic devices 103 are then soldered to soldering pads of the PCB layer 111 by solder wires using a soldering iron or by solder pastes using an oven or furnace. Solder wires or solder pastes are used as the solder preform for soldering the free ends of the terminal pins of the power electronic devices 103 to the soldering pads of the PCB layer 111. A specific height is maintained between the device layer 102 and the PCB layer 111 based on the power electronic device package 100 design drawing so as to maintain a level where the components on top of the PCB layer 111 are not exposed during encapsulation, while components at the bottom of the PCB layer 111 will not be in contact with the other active components at the device layer 102 unless desired by the design. Jigs and fixtures are used to maintain the height and alignment. In another embodiment, the wire bonds 107 are also used to connect the PCB layer 111 to the device layer 102. Additional leads 105 are then mounted and soldered to the designated soldering pads of the control PCB assembly.

An encapsulant 106 encases 1505 the internal electronic circuit 104 formed by the power electronic devices 103 on the base member 101, a portion of the base member 101, and a portion of the leads 105 to assemble the power electronic device package 100. The encapsulant 106 is formed using a transfer molding technique. After assembling the power electronic device package 100, the power electronic device package 100 is mounted into a heated mold die set with mold cavities designed for the power electronic device package 100. An epoxy molding compound is then transferred through mold runners that extend to the mold cavities. The power electronic device package 100 is over molded with the thermoset epoxy molding compound to form the encapsulant 106 that holds the leads 105 and the base member 101. The power electronic device package 100 is then ejected after completion of the transfer molding technique. The opposing surface 101b of the base member 101 is rearwardly exposed on the power electronic device package 100.

In another embodiment, the encapsulant 106 is formed using the potting technique. The encapsulant 106, for example, a plastic case or a housing, is first attached to the base member 101 using a non-conductive epoxy material. After a curing process, a liquid potting material is poured into the encapsulant 106 until the desired level is achieved. The liquid potting material is, for example, a liquid resin etc. Curing is performed at room temperature. In an embodiment, an oven is used to perform curing at elevated temperatures.

The transfer molded package is then cleaned, marked, and further cured. The transfer molded package comprising the encased internal electronic circuit 104 formed by the power electronic devices 103 on the base member 101, the portion of the base member 101, and the portion of the leads 105 in strip form is then singulated 1506 to create the power electronic device package 100. As used herein, “singulating” refers to separating identifiable units that are not necessarily detached from one another. Other processes are then performed to finish the power electronic device package 100 into a final and desired product. The tie bars of the leads 105 are trimmed, for example, manually, using a trim die set, etc. The unnecessary leads 105 are then removed. In an embodiment, external signal leads 105 are also formed, if required. The power electronic device package 100 is then tested and sorted accordingly based on the power rating of the power electronic device package 100. Internal drive and control circuits, protection circuits and other circuits can be integrated into the power electronic device package 100 during assembly prior to the transfer molding process for implementation as an intelligent power module.

The foregoing examples have been provided merely for the purpose of explanation and are in no way to be construed as limiting of the present invention disclosed herein. While the invention has been described with reference to various embodiments, it is understood that the words, which have been used herein, are words of description and illustration, rather than words of limitation. Further, although the invention has been described herein with reference to particular means, materials, and embodiments, the invention is not intended to be limited to the particulars disclosed herein; rather, the invention extends to all functionally equivalent structures, methods and uses, such as are within the scope of the appended claims. Those skilled in the art, having the benefit of the teachings of this specification, may affect numerous modifications thereto and changes may be made without departing from the scope and spirit of the invention in its aspects.

I claim:

1. A power electronic device package, comprising:
a base member, thermally conductive for heat dissipation;
a device layer comprising one or more power electronic devices mounted on said base member, wherein said one or more power electronic devices are selectively electrically connected to each other and to said base member to form an internal electronic circuit;
a plurality of leads extending outwardly from said base member and electrically connected to said internal electronic circuit formed by said one or more power electronic devices on said base member; and
an encapsulant encasing said internal electronic circuit formed by said one or more power electronic devices on said base member, a portion of said base member, and a portion of said plurality of leads;
whereby said power electronic device package is configured as a power module with said plurality of leads and increased power handling capability.

2. The power electronic device package of claim 1, wherein said base member is isolatably connected to said internal electronic circuit formed by said selective electrical connection of said one or more power electronic devices to each other and to said plurality of leads.

3. The power electronic device package of claim 1, further comprising a substrate mounted on said base member for selectively isolating said one or more power electronic devices on said device layer from each other and from said base member.

4. The power electronic device package of claim 3, wherein said substrate is one of a metallized substrate and a direct copper bonded substrate.

5. The power electronic device package of claim 3, wherein said substrate is made of a material comprising one or more of aluminum nitride and aluminum oxide.

6. The power electronic device package of claim 1, wherein said one or more power electronic devices are directly mounted on one of said base member, a substrate mounted on said base member, and a combination thereof.

7. The power electronic device package of claim 1, further comprising a printed circuit board layer comprising one or more of complementary electronic devices and auxiliary electronic devices disposed in conjunction with said device layer mounted on one of said base member and a substrate mounted on said base member.

8. The power electronic device package of claim 7, wherein said printed circuit board layer is one of directly mounted on top of said device layer and mounted adjacent to said device layer.

9. The power electronic device package of claim 1, wherein an opposing surface of said base member is rearwardly exposed in said power electronic device package.

10. The power electronic device package of claim 1, further comprising one or more mounting holes for enabling direct installation to an external heat sink.

11. The power electronic device package of claim 1, wherein said base member is electrically conductive and configured to operate as an active electrical terminal for connection to said internal electronic circuit formed by said one or more power electronic devices mounted on said base member.

12. The power electronic device package of claim 1, wherein said base member comprises a mounting area that enables said mounting of said one or more power electronic devices in a plurality of configurations.

13. The power electronic device package of claim 1, wherein said mounted one or more power electronic devices are selectively connected to each other and to said base member by one of wire bonds, soldered interconnects, and a combination thereof to form said internal electronic circuit.

14. The power electronic device package of claim 1, wherein said base member is one of a copper base member, a direct copper bonded substrate, and a combination of said copper base member and said direct copper bonded substrate.

15. The power electronic device package of claim 1, wherein said plurality of leads comprises one of power leads, signal leads, and a combination thereof.

16. The power electronic device package of claim 1, wherein said plurality of leads is selectively combinable to increase current handling capacity of said plurality of leads and said power electronic device package.

17. The power electronic device package of claim 1 configured as a transfer molded power module in an expanded transistor outline package.

18. A method for creating a power electronic device package configured as a power module with a plurality of leads and increased power handling capability, comprising:
providing a base member thermally conductive for heat dissipation;
mounting a device layer comprising one or more power electronic devices on said base member, wherein said one or more power electronic devices are selectively electrically connected to each other and to said base member to form an internal electronic circuit;
electrically connecting said plurality of leads to said internal electronic circuit formed by said one or more power electronic devices on said base member, wherein said plurality of leads extend outwardly from said base member;
encasing said internal electronic circuit formed by said one or more power electronic devices on said base member, a portion of said base member, and a portion of said plurality of leads by an encapsulant; and
singulating said encased internal electronic circuit formed by said one or more power electronic devices on said base member, said portion of said base member, and said portion of said plurality of leads to create said power electronic device package.

19. The method of claim 18, further comprising isolatably connecting said base member to said internal electronic circuit formed by said selective electrical connection of said one or more power electronic devices to each other and to said plurality of leads.

20. The method of claim 18, further comprising mounting a substrate on said base member for selectively isolating said one or more power electronic devices on said device layer from each other and from said base member.

21. The method of claim 18, further comprising mounting a printed circuit board layer comprising one or more of complementary electronic devices and auxiliary electronic devices on top of said device layer or adjacent to said device layer mounted on one of said base member and a substrate mounted on said base member.

22. The method of claim 21, wherein said printed circuit board layer is connected to said device layer by one of jumper wires, soldered connecting terminal pins, wire bonded aluminum wires, wire bonded gold wires, and any combination thereof.

23. The method of claim 18, further comprising paralleling said power electronic devices on said base member that serves as a common active terminal, to achieve high current ratings.

24. The method of claim 18, wherein said one or more power electronic devices are mounted on one of said base member, a substrate mounted on said base member, and a combination thereof, via one of one or more mounting pads, a supplementary substrate, and a combination thereof.

25. The method of claim 18, wherein said base member is electrically conductive and configured to operate as an active electrical terminal for connection to said internal electronic circuit formed by said one or more power electronic devices mounted on said base member.
